(19) United States
(12) Patent Application Publication
(10) Pub. No.: US 2017/0111736 A1
(43) Pub. Date: Apr. 20, 2017

(54) Audio bass compensation system and compensation method

(71) Applicants: Huan Ge, Shenzhen (CN); Hongxing Wang, Shenzhen (CN); Rongguan Zhou, Shenzhen (CN); Lijian Ye, Shenzhen (CN)

(72) Inventors: Huan Ge, Shenzhen (CN); Hongxing Wang, Shenzhen (CN); Rongguan Zhou, Shenzhen (CN); Lijian Ye, Shenzhen (CN)

(73) Assignee: AAC ACOUSTIC TECHNOLOGIES (SHENZHEN) CO., LTD, Shenzhen (CN)

(21) Appl. No.: 15/228,246

(22) Filed: Aug. 4, 2016

(30) Foreign Application Priority Data
Oct. 16, 2015 (CN) 201510674372.7

(51) Int. Cl. H04R 3/04; H03F 3/68; H03F 3/183; H03G 5/16

(52) U.S. Cl. CPC H04R 3/04; H03G 5/165; H03F 3/68; H03F 3/183; H04R 2499/11; H03F 2200/165

(57) ABSTRACT

An audio bass compensation system is disclosed. The audio bass compensation system includes a first signal path and a second signal path which are set in parallel. The first signal path includes a first equalizer, a first phase correction unit, a first power amplifier, a receiver or speaker. The second signal path includes a second equalizer, a second phase correction unit, a second power amplifier and a bass speaker which are connected electrically in series. Compared with the related technology, the audio bass compensation system adopts the receiver or the speaker to provide the medium-high compensation to the bass speaker. The present invention also provides a compensation method for audio bass compensation system.

### FIELD OF THE INVENTION

The present invention relates to the technical field of mobile phone audio system, specifically, relates to an audio bass compensation system and the compensation method.

### DESCRIPTION OF RELATED ART

In the existing technology, mobile phone includes a receiver and a speaker. The receiver is used for hand-hold talking. The speaker is used for hands-free talking and multimedian audio signal replay. When the receiver at working status is close to the ear of the person, it is required to provide better acoustic response in near field, thereby, the receiver shall have lower rated power, and the rated impedance shall be bigger, 32 ohms in general. On the other hand, in the mobile phone structural design of the existing technology, the receiver is usually located at the mobile phone heat and the closed back cavity is not required, therefore, the external dimension of the telephone receiver is limited by the mobile phone head space. In order to realize the audio signal replay at far field, the rated power of the speaker is relatively bigger, and the rated impedance is 4-8 ohms in general.

In related technologies, the mobile phone audio system adopts common mobile phone speaker, and does not adopt a special bass speaker. There are no cases that the speaker is used as telephone receiver. In practical application, the phase match between the receiver and the speaker is not considered also. The sensitivity of common speaker is generally lower than high power speaker, and the low frequency replay performance of the common mobile phone speaker system is low.

For this reason, it is necessary to provide a new audio bass compensation system and compensation method to solve the technical problems above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an illustration diagram of an audio bass compensation system in accordance with a first exemplary embodiment of the present disclosure.

FIG. 2 is a flow chart of a compensation method of the audio bass compensation system in FIG. 1.

FIG. 3 is an illustration diagram of an audio bass compensation system in accordance with a second exemplary embodiment of the present disclosure.

FIG. 4 is an illustration diagram of an audio bass compensation system in accordance with a third exemplary embodiment of the present disclosure.

FIG. 5 is an illustration diagram of an audio bass compensation system in accordance with a fourth exemplary embodiment of the present disclosure.

FIG. 6 is an illustration diagram of an audio bass compensation system in accordance with a fifth exemplary embodiment of the present disclosure.

### DETAILED DESCRIPTION OF THE EXEMPLARY EMBODIMENTS

The present invention will hereinafter be described in detail with reference to exemplary embodiments. To make the technical problems to be solved, technical solutions and beneficial effects of present disclosure more apparent, the present disclosure is described in further detail together with the figures and the embodiments. It should be understood the specific embodiment described hereby is only to explain this disclosure, not intended to limit this disclosure.

### Embodiment 1

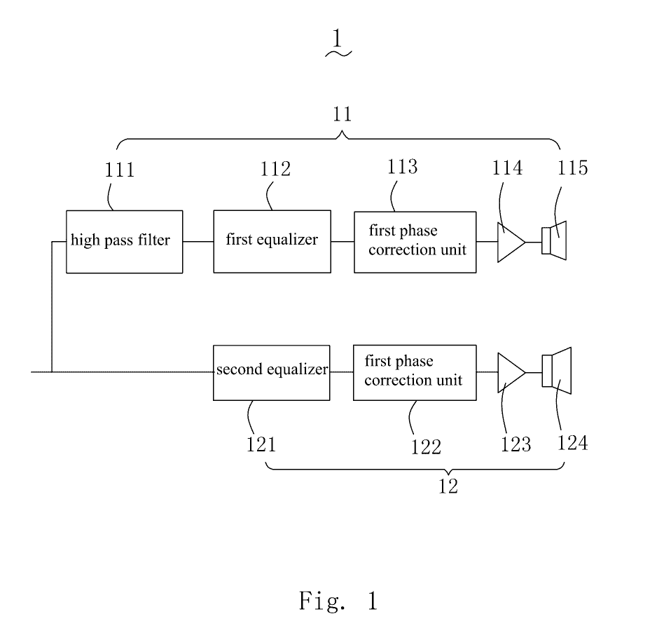

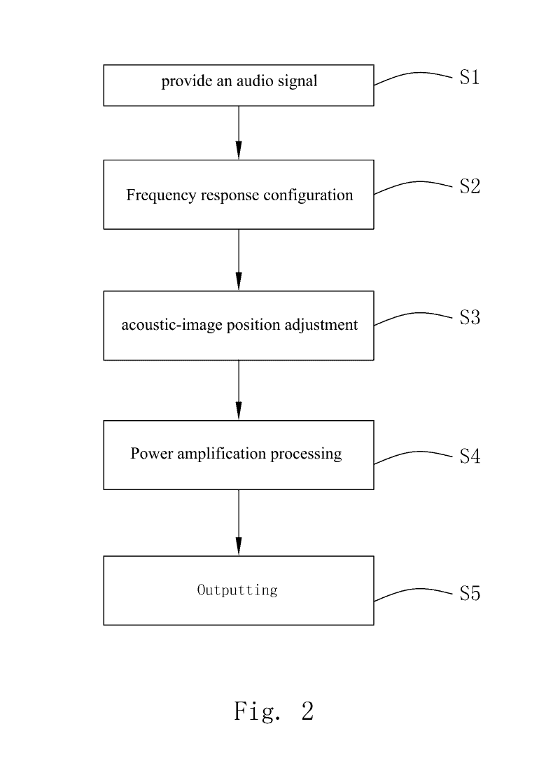

Referring to FIG. 1 and FIG. 2, an audio bass compensation system 1 includes a first signal path 11 and a second signal path 12 which are set in parallel. The first signal path 11 includes a high pass filter 111, a first equalizer 112, a first phase correction unit 113, a first power amplifier 114 and a receiver 115 which are connected electrically in series in turn. The second signal path 12 includes a second equalizer 121, a second phase correction unit 122, a second power amplifier 123 and a bass speaker 124 which are connected electrically in series in turn, of which, the receiver 115 provides medium-high frequency compensation when the bass speaker 124 works.

The first signal path 11 and the second signal path 12 are used for transmitting audio signal. When the audio bass compensation system 1 works, the first signal path 11 and the second signal path 12 which are set in parallel are matched for bass compensation. The working principle is as follows:

S1, provide an audio signal which is single channel audio signal.

S2, Frequency response configuration: Along the first signal path 11, the single channel audio signal is filtered by the high pass filter 111 and is transmitted to the first equalizer 112. The high pass filter 111 filters one part of the low frequency signals, in case excessive low frequency signals damage the receiver 115 due to excessive vibration amplitude. The high pass filter increases also the medium high frequency sensitivity of the receiver 115 in working. And then, the first equalizer 112 adjusts the single channel audio signal filtered by the high pass filter. Along the second signal path 12, the single channel audio signal is adjusted by the second equalizer 121 at the same time.

In this step, the single channel audio signal is regulated by the first equalizer 112 and the second equalizer 121, so that the frequency response of the receiver 115 and the bass speaker 124 when working together is set at the preset effect status.

S3, acoustic-image position adjustment: Along the first signal path 11, the single channel audio signal after being adjusted by the first equalizer 112 passes the first equalizer 112. The audio signal with the frequency response configured by the first equalizer 112 is transmitted to the first phase correction unit 113. Along the second signal path 12, the single channel audio signal is adjusted by the second equalizer 121 at the same time. The audio signal with the frequency response configured by the second equalizer 121 is transmitted to the second phase correction unit 122.

In this step, the first phase correction unit 113 corrects the phase of the audio signal after frequency response configuration to the preset listening position. The phase mismatch of the receiver 115 and the bass speaker 124 due to different frequency response, different structure and positions is corrected and the acoustic image is concentrated on suitable listening position. The second phase correction unit 122 corrects the phase of the audio signal after frequency response configuration to the preset listening position. The phase mismatch of the bass speaker 124 and the receiver 115 due to different frequency response, different structure and positions is corrected and the acoustic image is concentrated on suitable listening position.

S4, Power amplification processing: Along the first signal path 11, the single channel audio signal with the acoustic image position adjusted in the first phase correction unit 113 is transmitted to the first power amplifier 114. At the same time, along the second signal path 12, the single channel audio signal with the acoustic image position adjusted in the second phase correction unit 122 is transmitted to the second power amplifier 123. The audio signal with the acoustic image position adjusted is amplified by the second power amplifier 123.

S5, Output: Along the first signal path 11, the audio signal amplified by the first power amplifier is transmitted to the receiver 115. At the same time, along the second signal path 12, the audio signal amplified by the second power amplifier 123 is transmitted to the bass speaker 124. The receiver 115 and the bass speaker 124 export synchronously the audio signal amplified by the power amplifiers, so as to realize the medium-high frequency compensation of the receiver 115 on the bass speaker 124 in working.

### Embodiment 2

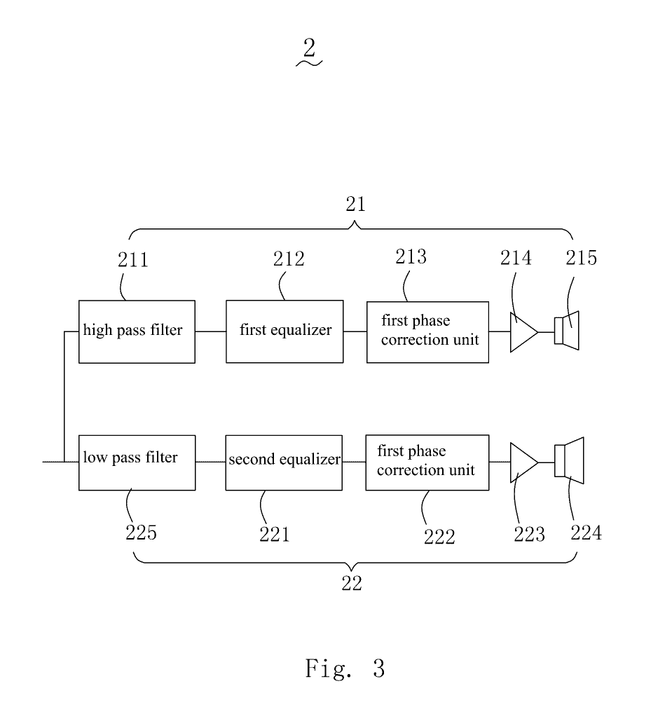

Referring to FIGS. 2-3, an audio bass compensation system 2 includes a first signal path 21 and a second signal path 22 which are set in parallel. The first signal path 21 includes a high pass filter 211, a first equalizer 212, a first phase correction unit 213, a first power amplifier 214 and a receiver 215 which are connected electrically in series in turn. The second signal path 22 includes a second equalizer 221, a second phase correction unit 222, a second power amplifier 223 and a bass speaker 224 which are connected electrically in series in turn. Preferably, the second signal path 22 includes also a low pass filter 225. The low pass filter 225 is connected serially with the second equalizer 221. The low pass filter 225 is located at the farther side of the second equalizer 221 to the second phase correction unit 222.

The first signal path 21 and the second signal path 22 are used for transmitting audio signal. The low-pass filter 225 in the second signal path 22 filters out low frequency signal, thereby enhances the bass replay performance.

When the audio bass compensation system 2 works, the first signal path 21 and the second signal path 22 which are set in parallel are cooperated for bass compensation. Its working principle is as follows:

S1, Audio signal is provided: The audio signal is single channel audio signal.

S2, Frequency response configuration: Along the first signal path 21, the single channel audio signal is filtered by the high pass filter 211. The audio signal filtered by the high pass filter 211 is transmitted to the first equalizer 212. The high pass filter 211 filters one part of the low frequency signals, in case excessive low frequency signals damage the receiver 215 due to excessive vibration amplitude. The high pass filter increases also the medium high frequency sensitivity of the receiver 215 in working. Along the second signal path 22, the single channel audio signal is transmitted to the low-pass filter 225. The low-pass filter 225 filters some of low frequency signals. The single channel audio signal filtered by the low-pass filter 225 is transmitted to the second equalizer 221.

In this step, the single channel audio signal is regulated by the first equalizer 212 and the second equalizer 221, so that the frequency of the receiver 215 and the bass speaker 224 when working together respond to the preset effect status.

S3, Acoustic-image position adjustment: Along the first signal path 21, the audio signal following the above mentioned frequency response configuration in the first equalizer 212 is transmitted to the first phase correction unit 213. Along the second signal path 22, the audio signal following the above mentioned frequency response configuration in the second equalizer 221 is transmitted to the first phase correction unit 222.

In this step, the first phase correction unit 213 corrects the phase of the audio signal after frequency response configuration to the preset listening position. The phase mismatch of the receiver 215 and the bass speaker 224 due to different frequency response, different structure and positions is corrected and the acoustic image is concentrated at suitable listening position. The second phase correction unit 222 corrects the phase of the audio signal after frequency response configuration to the preset listening position. The phase mismatch of the bass speaker 224 and the receiver 215 due to different frequency response, different structure and positions is corrected and the acoustic image is concentrated at suitable listening position.

S4, Power amplification processing: Along the first signal path 21, the single channel audio signal following the above mentioned acoustic image position adjustment in the first phase correction unit 213 is transmitted to the first power amplifier 214. Along the second signal path 22, the single channel audio signal following the above mentioned acoustic image position adjustment in the second phase correction unit 222 is transmitted to the second power amplifier 223. The audio signal following the acoustic image position adjustment is amplified by the second power amplifier 223.

S5, Output: Along the first signal path 21, the audio signal amplified by the first power amplifier 214 is transmitted to the receiver 215. Along the second signal path 22, the audio signal amplified by the second power amplifier 223 is transmitted also to the bass speaker 224. The receiver 215 and the bass speaker 224 export synchronously the audio signal with the power amplified by the power amplifiers, so as to realize the medium-high frequency compensation of the receiver 215 on the bass speaker 224 in working.

### Embodiment 3

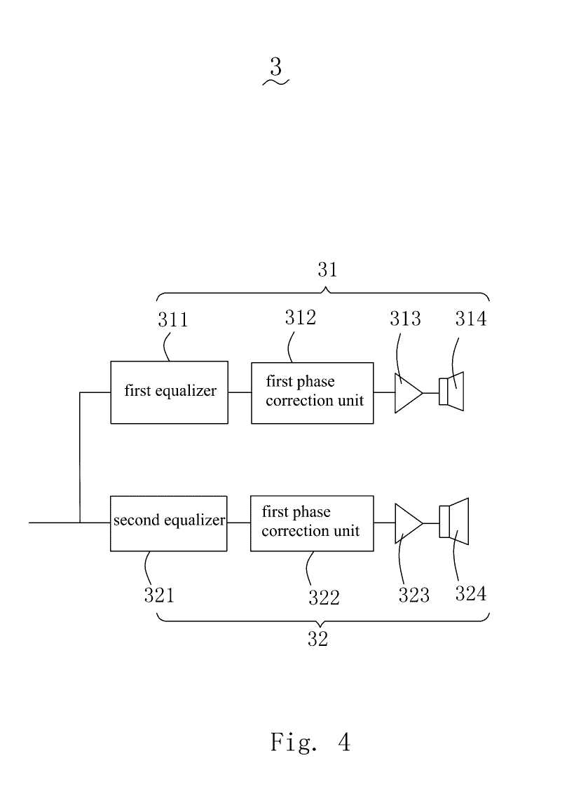

Referring to FIGS. 2 and 4, an audio bass compensation system 3 includes a first signal path 31 and a second signal path 32 which are set in parallel. The first signal path 31 includes the first equalizer 311, a first phase correction unit 312, a first power amplifier 313 and a speaker 314 which are connected electrically in series in turn. The second signal path 32 includes a second equalizer 321, a second phase correction unit 322, a second power amplifier 323 and a bass speaker 324 which are connected electrically in series in turn, of which, the speaker 314 provides the high frequency compensation when the bass speaker 324 works.

The first signal path 31 and the second signal path 32 are used respectively for transmitting audio signal. In hands-free calls or multimedia audio replay, the speaker 314 used as the receiver has good sensitivity and the bass speaker 324 has good bass. The speaker 314 and the bass speaker 324 are coordinated and compensated each other in the first equalizer 311 and the second equalizer 321. The first phase correction unit 312 and the second phase correction unit 322 correct the phase of the audio signal, so that the audio signal has good low frequency response and keeps high sensitivity at the same time.

When the audio bass compensation system 3 works, the first signal path 31 and the second signal path 32 which are set in parallel are cooperated for bass compensation. Its working principle is as follows:

S1, Providing audio signal: The audio signal is single channel audio signal.

S2, Frequency response configuration: Along the first signal path 31, the single channel audio signal is transmitted to the first equalizer 311. Along the second signal path 32, the single channel audio signal is transmitted to the second equalizer 321.

In this step, the single channel audio signal is regulated by the first equalizer 312 and the second equalizer 321, so that the frequency response of the receiver 314 and the bass speaker 324 when working together is set at the preset effect status.

S3, Acoustic-image position adjustment: Along the first signal path 31, the audio signal following the frequency response configuration in the first equalizer 311 is transmitted to the first phase correction unit 312. Along the second signal path 32, the audio signal following the frequency response configuration in the second equalizer 321 is transmitted to the second phase correction unit 322.

In this step, the first phase correction unit 312 corrects the phase of the audio signal after frequency response configuration to the preset listening position. The phase mismatch of the speaker 314 and the bass speaker 324 due to different frequency response, different structure and positions is corrected and the acoustic image is concentrated on suitable listening position. The second phase correction unit 322 corrects the phase of the audio signal after frequency response configuration to the preset listening position. The phase mismatch of the bass speaker 324 and the speaker 314 due to different frequency response, different structure and positions is corrected and the acoustic image is concentrated at suitable listening position.

S4, Power amplification processing: Along the first signal path 31, the single channel audio signal following the acoustic image position adjustment in the first phase correction unit 312 is transmitted to the first power amplifier 313. Along the second signal path 32, the single channel audio signal following the acoustic image position adjustment in the second phase correction unit 322 is transmitted to the second power amplifier 323. The audio signal following the listening position adjustment is amplified by the first power amplifier 313 and the second power amplifier 323.

S5, Output: Along the first signal path 31, the audio signal amplified by the first power amplifier 313 is transmitted to the speaker 314. Along the second signal path 32, the audio signal amplified by the second power amplifier 323 is transmitted to the bass speaker 324. The speaker 314 and the bass speaker 324 export synchronously the audio signal with the power amplified by the power amplifiers, so as to realize the medium-high frequency compensation of the speaker 314 on the bass speaker 324 in working.

### Embodiment 4

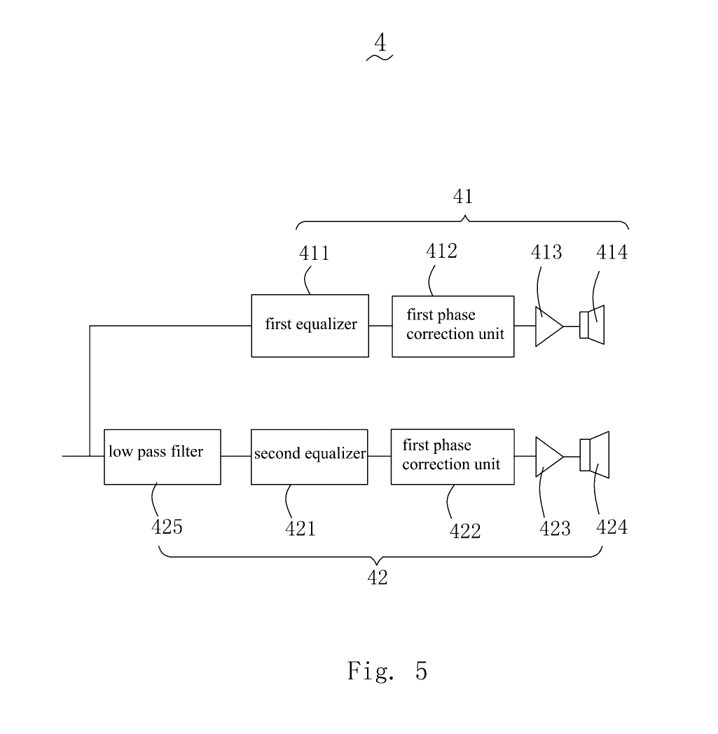

Referring to FIGS. 2 and 5, an audio bass compensation system 4 includes a first signal path 41 and a second signal path 42 which are set in parallel. The first signal path 41 includes the first equalizer 411, the first phase correction unit 412, the first power amplifier 413 and the speaker 414 which are connected electrically in series in turn. The second signal path 42 includes the second equalizer 421, the second phase correction unit 422, the second power amplifier 423 and the bass speaker 424 which are connected electrically in series in turn. The second signal path 42 includes also the low pass filter 425, which is connected with the second equalizer 421 in series. The low pass filter 425 is located at the side of the second equalizer 421 which is farther away the second phase correction unit 422.

The first signal path 41 and the second signal path 42 are used for transmitting audio signal. In hands-free calls or multimedia audio replay, the speaker 414 is used as the receiver and works in normal frequency band, the bass speaker 424 works only in its adequate low frequency band, thereby provides bass compensation to the bass speaker 424.

When the audio bass compensation system 4 works, the first signal path 41 and the second signal path 42 which are set in parallel are cooperated for bass compensation. Its working principle is as follows:

S1, Providing audio signal: The audio signal is single channel audio signal.

S2, Frequency response configuration: Along the first signal path 41, the single channel audio signal is transmitted to the first equalizer 411. Along the second signal path 42, the single channel audio signal is transmitted to the low-pass filter 425. The low-pass filter 425 filters part of high-frequency signal. The audio signal filtered in the low-frequency filter is transmitted to the second equalizer 421.

In this step, the single channel audio signal is regulated by the first equalizer 411 and the second equalizer 421, so that the frequency response of the speaker 414 and the bass speaker 424 when working together is set at the preset effect status.

S3, Acoustic-image position adjustment: Along the first signal path 41, the audio signal following the frequency response configuration in the first equalizer 411 is transmitted to the first phase correction unit 412. Along the second signal path 42, the audio signal following the frequency response configuration in the second equalizer 421 is transmitted to the first phase correction unit 422.

In this step, the first phase correction unit 412 corrects the phase of the audio signal after frequency response configuration to the preset listening position. The phase mismatch of the speaker 414 and the bass speaker 424 due to different frequency response, different structure and positions is corrected and the acoustic image is concentrated on suitable listening position. The second phase correction unit 422 corrects the phase of the audio signal after frequency response configuration to the preset listening position. The phase mismatch of the bass speaker 424 and the speaker 414 due to different frequency response, different structure and positions is corrected and the acoustic image is concentrated at suitable listening position.

S4, Power amplification processing: Along the first signal path 41, the single audio signal following the acoustic image position adjustment in the first phase correction unit 412 is transmitted to the first power amplifier 413. Along the second signal path 42, the single audio signal following the acoustic image position adjustment in the second phase correction unit 422 is transmitted to the second power amplifier 423. The audio signal with the listening is amplified by the first power amplifier 413 and the second power amplifier 423.

S5, Output: Along the first signal path 41, the audio signal amplified by the first power amplifier 413 is transmitted to the speaker 414. Along the second signal path 42, the audio signal amplified by the second power amplifier 423 is transmitted to the bass speaker 424. The speaker 414 and the bass speaker 424 export synchronously the audio signal amplified by the power amplifiers, so as to realize the medium-high frequency compensation of the speaker 414 on the bass speaker 424 in working.

### Embodiment 5

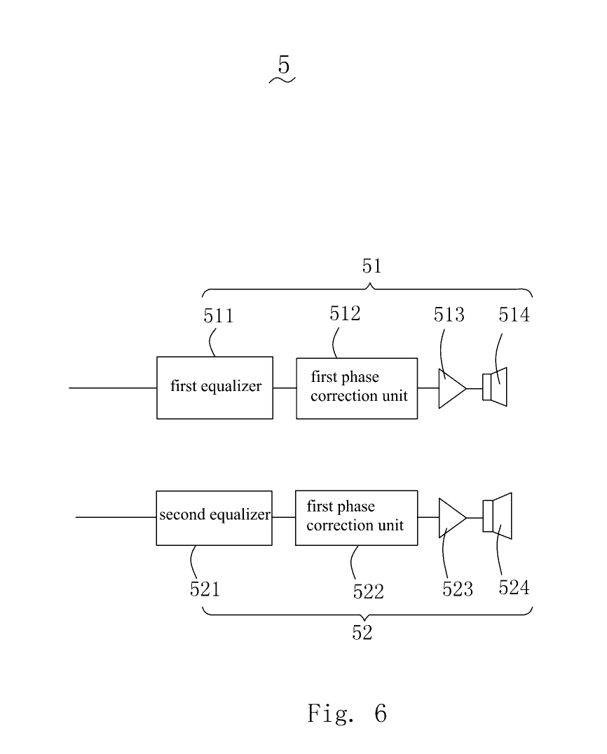

Referring to FIGS. 2 and 6, an audio bass compensation system 5 includes a first signal path 51 and a second signal path 52 which are set in parallel. The first signal path 51 includes the first equalizer 511, the first phase correction unit 512, the first power amplifier 513 and the speaker 514 which are connected electrically in series in turn. The second signal path 52 includes the second equalizer 521, the second phase correction unit 522, the second power amplifier 523 and the bass speaker 524 which are connected electrically in series.

The stereo double track signal is transmitted to the speaker 514 which is used as the receiver, and the first signal path 51 and the second signal path 52 where the bass speaker 524 is located. The equalizer 511 and the equalizer 512, the first phase correction unit 512 and the second phase correction unit 522 set up corresponding parameters according to the frequency response characteristic as well as position of the speaker 514 and the bass speaker 524, and correct the frequency response of the listening position and the stereo acoustic image, resynchronize the output from the speaker 514 and the bass speaker 524.

When the audio bass compensation system 5 works, the first signal path 51 and the second signal path 52 which are set in parallel are cooperated for bass compensation. Its working principle is as follows:

S1, Audio signal is provided: The audio signal is double track signal.

S2, Frequency response configuration: Along the first signal path 51, one audio signal of the double track signal is transmitted to the first equalizer 511. Along second signal path 52, another audio signal of the double track signal is transmitted to the second equalizer 521.

In this step, the single channel audio signal is regulated by the first equalizer 511 and the second equalizer 521, so that the frequency response of the speaker 514 and the bass speaker 524 when working together is set at the preset effect status.

S3, Acoustic-image position adjustment: Along the first signal path 51, the audio signal with the frequency response configured in the first equalizer 511 is transmitted to the first phase correction unit 512. Along the second signal path 52, the audio signal with the frequency response configured in the second equalizer 521 is transmitted to the first phase correction unit 522.

In this step, the first phase correction unit 512 corrects the phase of the audio signal after frequency response configuration to the preset listening position. The phase mismatch of the speaker 514 and the bass speaker 524 due to different frequency response, different structure and positions is corrected and the acoustic image is concentrated on suitable listening position. The second phase correction unit 522 corrects the phase of the audio signal after frequency response configuration to the preset listening position. The phase mismatch of the bass speaker 524 and the speaker 514 due to different frequency response, different structure and positions is corrected and the acoustic image is concentrated at suitable listening position.

S4, Power amplification processing: Along the first signal path 51, the single audio signal following the acoustic image position adjustment in the first phase correction unit 512 is transmitted to the first power amplifier 513. Along the second signal path 52, the single audio signal following the acoustic image position adjustment in the second phase correction unit 522 is transmitted to the second power amplifier 523. The audio signal following the listening position adjustment is amplified by the first power amplifier 513 and the second power amplifier 523.

S5, Output: Along the first signal path 51, the audio signal amplified by the first power amplifier 513 is transmitted to the speaker 514. Along the second signal path 52, the audio signal amplified by the second power amplifier 523 is transmitted to the bass speaker 524. The speaker 514 and the bass speaker 524 export synchronously the audio signal with the power amplified by the power amplifiers, so as to realize the medium-high frequency compensation of the speaker 514 on the bass speaker 524 in working.

Compared with the relevant technology, the audio bass compensation system disclosed in this invention includes the first signal path and the second signal path which are set in parallel. The first signal path includes the high pass filter, the first equalizer, the first phase correction unit, the first power amplifier and the receiver which are connected electrically in series. The first signal path includes the first equalizer, the first phase correction unit, the first power amplifier and the speaker which are connected electrically in series. The second signal path includes the second equalizer, the second phase correction unit, the second power amplifier and the bass speaker which are connected electrically in series. The audio bass compensation system adopts the receiver or the speaker to provide the medium-high compensation to the bass speaker. The first phase correction unit and the second phase correction unit match the phases between the receiver or the speaker and the bass speaker, so that the audio bass compensation system has better low frequency performance, as well as high quality medium-high frequency sensitivity.

It is to be understood, however, that even though numerous characteristics and advantages of the present exemplary embodiment have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An audio bass compensation system, comprising:
a first signal path including a high pass filter, a first equalizer, a first phase correction unit, a first power amplifier and a receiver which are connected electrically in series in turn;
a second signal path parallel connected with the first signal path, including a second equalizer, a second phase correction unit, a second power amplifier and a bass speaker which are connected electrically in series in turn; wherein
the receiver provides medium-high frequency compensation when the bass speaker works.

2. The audio bass compensation system according to claim 1, wherein the second signal path further includes a low pass filter connected with the second equalizer in series.

3. A compensation method for the audio bass compensation system as described in claim 1, comprising following steps:
providing a first signal path and the second signal path which are set in parallel, the first signal path including a high pass filter, a first equalizer, a first phase correction unit, a first power amplifier and a receiver which are connected electrically in series in turn, the second signal path including a second equalizer, a second phase correction unit, a second power amplifier and a bass speaker which are connected electrically in series in turn;
providing an audio signal;
providing frequency response configuration, wherein, the audio signal is transmitted respectively to the high-pass filter and the second equalizer; after being filtered by the high-pass filter, the audio signal is transmitted to the first equalizer; the audio signal is adjusted by the first equalizer and the second equalizer;
providing acoustic-image position adjustment, wherein, the audio signal following the above mentioned frequency response configuration is transmitted respectively to the first phase correction unit and the second phase correction unit by the first equalizer and the second equalizer, the audio signal following the above mentioned frequency response configuration is corrected in phase to the preset listening position by the first phase correction unit and the second phase correction unit;
providing power amplification processing, wherein, the audio signal following the above mentioned acoustic-image position adjustment is transmitted respectively to the first power amplifier and the second power amplifier by the first phase correction unit and the second phase correction unit, the audio signal following the above mentioned acoustic-image position adjustment is amplified by the first power amplifier and the second power amplifier;
outputting, wherein the audio signal following the above mentioned power amplification processing is transmitted to the receiver and the bass speaker by the first power amplifier and the second power amplifier, the audio signal following the above mentioned power amplification processing is outputted synchronously by the receiver and the bass speaker, for realizing the medium-high frequency compensation of the receiver on the bass speaker during working.

4. The compensation method according to claim 3, wherein the second signal path further includes a low pass filter which is connected serially with the second equalizer, in the step of frequency response configuration, before the audio signal is transmitted to the second equalizer, the audio signal filtered by the low-pass filter is transmitted to the second equalizer.

5. An audio bass compensation system, comprising:
a first signal path including a first equalizer, a first phase correction unit, a first power amplifier and a speaker which are connected electrically in series in turn;
a second signal path parallel connected with the first signal path, the second signal path including a second equalizer, a second phase correction unit, a second power amplifier a the bass speaker which are connected electrically in series in turn; wherein
the speaker provides medium-high frequency compensation when the bass speaker works.

6. The audio bass compensation system according to claim 5, wherein the second signal path further includes a low pass filter connected with the second equalizer in series.

7. A compensation method of the audio bass compensation system as described in claim 5, including following steps:
providing a first signal path and the second signal path which are set in parallel, the first signal path including a first equalizer, a first phase correction unit, a first power amplifier and a speaker which are connected electrically in series in turn, the second signal path including a second equalizer, a second phase correction unit, a second power amplifier and a bass speaker which are connected electrically in series in turn;
providing an audio signal;
providing frequency response configuration, wherein, the audio signal is transmitted respectively to the first equalizer and the second equalizer; after being filtered by the high-pass filter, the audio signal is transmitted to the first equalizer; the audio signal is adjusted by the first equalizer and the second equalizer;
providing acoustic-image position adjustment, wherein, the audio signal following the above mentioned frequency response configuration is transmitted respectively to the first phase correction unit and the second phase correction unit by the first equalizer and the second equalizer, the audio signal following the above mentioned frequency response configuration is corrected in phase to the preset listening position by the first phase correction unit and the second phase correction unit;
providing power amplification processing, wherein, the audio signal following the above mentioned acoustic-image position adjustment is transmitted respectively to the first power amplifier and the second power amplifier by the first phase correction unit and the second phase correction unit, the audio signal following the above mentioned acoustic-image position adjustment is amplified by the first power amplifier and the second power amplifier;
outputting, wherein the audio signal following the above mentioned power amplification processing is transmitted to the speaker and the bass speaker by the first power amplifier and the second power amplifier, the audio signal following the above mentioned power amplification processing is outputted synchronously by the speaker and the bass speaker, for realizing the medium-high frequency compensation of the speaker on the bass speaker during working.

8. The compensation method according to claim 7, wherein i the second signal path further includes a low pass filter, which is connected with the second equalizer in series, in step of frequency response configuration, before the audio signal is transmitted to the second equalizer, the audio signal is firstly transmitted to the low-pass filter for frequency filtration then it is transmitted to the second equalizer.
